(19) United States
(12) Patent Application Publication
(10) Pub. No.: US 2011/0268893 A1
(43) Pub. Date: Nov. 3, 2011

(54) THIN FILM MANUFACTURING DEVICE AND THIN FILM MANUFACTURING METHOD

(76) Inventors: Kazuyoshi Honda, Osaka, (JP); Tomofumi Yanagi, Osaka (JP); Yasuharu Shinokawa, Osaka (JP); Sadayuki Okazaki, Osaka (JP)

(21) Appl. No.: 13/143,284

(22) PCT Filed: Apr. 2, 2010
(86) PCT No.: PCT/JP2010/002445

§ 371 Date: Jul. 5, 2011

(30) Foreign Application Priority Data
Apr. 8, 2009 (JP) 2009-093807

(51) Int. Cl. C23C 14/30

(52) U.S. Cl. 427/596; 118/723 EB

(57) ABSTRACT

The present invention provides a thin film manufacturing device capable of preventing crack damage of a crucible by, while maintaining a melt state of a film formation material in the crucible, tilting the crucible to discharge substantially the entire amount of film formation material from the crucible. The thin film manufacturing device of the present invention includes: a film forming source 9 including a storage portion having an opening at an upper portion thereof to hold a film formation material 3; an electron gun 5 configured to irradiate the film formation material in the storage portion with an electron beam 6 to melt the film formation material, generate a melt, and evaporate the film formation material; a tilt mechanism 8 configured to tilt the film forming source 9 from a film formation posture to an inclined posture to discharge the melt from the storage portion, the inclined posture being a posture by which the storage portion is not able to hold the melt; a vacuum chamber 22 in which the film forming source and the tilt mechanism are accommodated and a thin film is formed on a substrate; and a vacuum pump 34 configured to discharge air in the vacuum chamber. A trajectory of tilting of the film forming source 9 or a trajectory of the electron beam 6 is controlled such that the melt in the storage portion is continuously irradiated with the electron beam 6 while the film forming source 9 is tilted from the film formation posture to the inclined posture.

### TECHNICAL FIELD

The present invention relates to a thin film manufacturing device and a thin film manufacturing method.

### BACKGROUND ART

A thin film formation technology is widely used to enhance device performances and reduce device sizes. Utilizing thin films in devices brings direct merits to users, and in addition, plays an important role from an environmental point of view, such as protection of earth resources and a reduction in power consumption.

For the development of the thin film formation technology, it is essential to respond to demands from industrial use aspects, such as increases in efficiency, stability, and productivity of the thin film manufacturing method and a reduction in cost of the thin film manufacturing method. Efforts toward these are being continued.

To improve the productivity of the thin film, a film formation technology capable of maintaining high deposition rate for a long period of time is essential. As such technology, in thin film manufacture using vacuum deposition, it is effective to use electron beam evaporation in which a deposition material is held in a heat-resistant crucible.

Used as a material constituting the heat-resistant crucible is alumina, magnesia, zirconia, carbon, boron nitride, or the like to prevent an unnecessary reaction with the deposition material.

PTL 1 discloses that an evaporation source crucible is tilted at about 10 to 20 degrees in the middle of the deposition to discharge and remove impurities, floating on the surface of a melt of the deposition material in the crucible, to the outside of the crucible.

PTL 2 discloses that the evaporation source crucible is tilted at an inclination angle of 3 to 45 degrees in the middle of the deposition to cause floating substances, such as oxides, floating on the surface of the melt of the deposition material in the crucible to adhere to an inner wall surface of the crucible, thereby removing the floating substances on the surface of the melt.

PTL 3 discloses that in order to avoid a case where the oxides getting mixed in the crucible through the inner wall of the crucible are impacted by an electron beam to be instantly scattered at high speed and damage the deposited film, the crucible is tilted after the completion of the film formation to discharge from the crucible the melt of cobalt-nickel that is a magnetic material.

PTL 4 discloses that in order to cool the melt in the crucible in a short period of time after the film formation, the melt of the magnetic material, such as cobalt or nickel, is discharged from the crucible by tilting the crucible after the film formation. Each of FIGS. 4 and 5 of PTL 4 shows that the crucible is tilted along a rotation axis that is one base of the crucible.

### CITATION LIST

### Patent Literature

PTL 1: Japanese Laid-Open Patent Application Publication No. 6-256935

PTL 2: Japanese Laid-Open Patent Application Publication No. 7-97680

PTL 3: Japanese Laid-Open Patent Application Publication No. 7-41938

PTL 4: Japanese Laid-Open Patent Application Publication No. 8-335316

### SUMMARY OF INVENTION

### Technical Problem

A large heat-resistant crucible is expensive. Therefore, to reduce the production cost, it is desired that the crucible be repeatedly used.

Factors determining the life of the crucible are the deterioration of the inner surface of the crucible and a crack damage that is cracking of the crucible itself, the deterioration being caused by, for example, a reaction between the material of the crucible and the deposition material.

If the crack damage occurs, the melt flows out through a cracked portion. Therefore, not only the damage of the crucible itself but also the damages of film formation equipment, the stop of the production, and the like may occur.

Causes of the occurrence of the crack damage are a thermal impact at the time of heating or cooling and a physical stress generated by the difference of expansion coefficient between the deposition material and the material of the crucible. Especially, after the electron beam evaporation is terminated, the melt in the crucible rapidly decreases in temperature and starts solidifying. Therefore, the crack damage of the crucible tends to occur. This phenomenon becomes prominent in a case where the difference of expansion coefficient between the deposition material and the material of the crucible is large. To prevent the crack damage of the crucible due to these causes, it is effective to slowly heat or cool the deposition material in the crucible when starting or terminating a thin film manufacturing process.

However, this solution causes an increase in time of the thin film manufacturing process, and this leads to the increase in the production cost. In addition, this solution is not a fundamental solution.

Especially, unlike common metal materials, silicon expands when it solidifies from a melt state by cooling. In contrast, the crucible contracts by cooling. Therefore, in the case of using silicon as the deposition material, extremely high stress is generated in the process of the solidification of silicon in the crucible after the film formation, and the crack damage of the crucible tends to occur.

To prevent the crack damage of the crucible, it is desired that the crucible is greatly tilted to discharge the entire amount of melt therefrom. In this case, the crucible is tilted up to an angle (larger than 90 degrees when the inner wall surface of the crucible is perpendicular to a horizontal plane) at which the crucible cannot hold the melt.

Further, to prevent silicon from solidifying in the crucible and discharge the entire amount of film formation material from the crucible, the melt state in the crucible needs to be maintained from the film formation until the completion of the discharge of the melt. To achieve this, it is necessary to continuously irradiate the melt with the electron beam from the film formation until the completion of the discharge of the melt such that the heating of the film formation material in the crucible is not stopped. This is because if the irradiation of the melt with the electron beam is stopped, the film formation material in the crucible may decrease in temperature, the melt may solidify, and as a result, the crack damage of the crucible may occur.

However, in a case where the crucible is simply tilted along the rotation axis that is one base of the crucible as shown in FIGS. 4 and 5 of PTL 4, and the inclination angle of the crucible reaches the above-described angle at which the crucible cannot hold the melt, the electron beam having irradiated the inside of the crucible is blocked by the crucible. As a result, the electron beam cannot irradiate the inside of the inclined crucible.

Each of PTLs 3 and 4 discloses that the melt is discharged from the crucible by tilting the crucible. The purpose of each of these techniques is to remove foreign matters from the melt or to perform rapid cooling of the melt outside the crucible. Any of the above PTLs do not disclose that substantially the entire amount of melt is discharged from the crucible for the purpose of preventing the crack damage of the crucible, and the melt state in the crucible is continuously maintained from the film formation until the completion of the discharge of the melt.

An object of the present invention is to provide a thin film manufacturing device and a thin film manufacturing method, each of which is capable of preventing the solidification of the film formation material in the crucible, discharging substantially the entire amount of film formation material from the crucible, and preventing the crack damage of the crucible, by tilting the crucible while maintaining the melt state of the film formation material in the crucible.

### Solution to Problem

The present inventors have solved the above problems in such a manner that the inside of the crucible that is a film forming source is continuously irradiated with the electron beam from the film formation until the completion of the discharge of the melt.

To solve the above problems, a thin film manufacturing device of the present invention includes: a film foaming source including a storage portion having an opening at an upper portion thereof to hold a film formation material; an electron gun configured to irradiate the film formation material in the storage portion with an electron beam to melt the film formation material, generate a melt, and evaporate the film formation material; a tilt mechanism configured to tilt the film forming source from a film formation posture to an inclined posture to discharge the melt from the storage portion, the inclined posture being a posture by which the storage portion is not able to hold the melt; a vacuum chamber in which the film forming source and the tilt mechanism are accommodated and a thin film is formed on a substrate; and a vacuum pump configured to discharge air in the vacuum chamber, wherein a trajectory of tilting of the film forming source or a trajectory of the electron beam is controlled such that the melt in the storage portion is continuously irradiated with the electron beam while the film forming source is tilted from the film formation posture to the inclined posture.

With the above configuration, the storage portion of the film forming source can be continuously irradiated with the electron beam from the film formation until the completion of the discharge of the melt. Therefore, the melt state in the storage portion can be maintained, and as a result, substantially the entire amount of film formation material can be discharged from the film forming source. Since the film formation material does not solidify in the crucible, the crack damage of the crucible can be prevented.

In the present invention, by providing outside the film forming source a rotation axis that is the center of tilting of the film forming source or by moving the rotation axis during the tilting, the trajectory of the tilting of the film forming source can be controlled such that the storage portion is continuously irradiated with the electron beam while the film forming source tilts from the film formation posture to the inclined posture at a maximum inclination angle. Moreover, by changing the trajectory of the electron beam during the tilting, the trajectory of the electron beam can be controlled such that the storage portion is continuously irradiated with the electron beam while the film forming source tilts from the film formation posture to the inclined posture at the maximum inclination angle.

In the present invention, the film formation posture is a posture by which the film formation material is held in the storage portion of the film forming source, and the opening of the film forming source faces upward and is opposed to a substrate surface on which the film is formed. In this posture, the film formation material in the storage portion is irradiated with the electron beam, and the evaporated film formation material is emitted from the opening and adheres to the opposed surface of the substrate. Thus, the film formation is performed. In this posture, the film formation material does not flow out of the film forming source.

The inclination angle at which the melt cannot be held in the storage portion of the film forming source is an angle at which substantially the entire amount of melt is discharged by the inclination of the film forming source. Specifically, for example, in a case where an inner wall surface of the film forming source is perpendicular to the horizontal plane, the inclination angle is an angle larger than 90 degrees. However, for example, in a case where the inner wall surface of the film forming source is not perpendicular to the horizontal plane, and the area of the inner bottom surface of the film forming source is smaller than the area of the opening thereof, substantially the entire amount of melt can be discharged from the storage portion of the film forming source even if the inclination angle is smaller than 90 degrees.

In accordance with PTLs 3 and 4, when the film forming source is inclined at the inclination angle at which the storage portion cannot hold the melt, the electron beam is blocked by the film forming source and cannot irradiate the inside of the storage portion. Therefore, the melt in the storage portion may decrease in temperature, and the film formation material may solidify in the storage portion before the melt is completely discharged. Therefore, the cracking of the crucible cannot be surely avoided.

Regarding the direction of the inclination of the film forming source when tilting the film forming source, it is preferable that the film forming source be tilted such that the melt is discharged in a direction in which an electron beam emission surface of the electron gun is located. To be specific, it is preferable that the film forming source be tilted such that the rotation axis when tilting the film forming source is substantially perpendicular to the trajectory of the electron beam on the horizontal plane, and the opening of the film forming source is inclined in the direction in which the electron beam emission surface of the electron gun is located. With this, as the film forming source tilts, the area of the opening of the film forming source when viewed from the electron beam emission surface increases. Therefore, it becomes easy to irradiate the film formation material in the film forming source with the electron beam. On this account, the melt state in the film forming source can be maintained more easily. However, in the present invention, the film forming source can tilt in a direction in which the rotation axis when tilting the film forming source is substantially parallel to the trajectory of the electron beam on the horizontal plane.

It is preferable that the thin film manufacturing device of the present invention further include a mechanism configured to deflect the trajectory of the electron beam. With this, the trajectory of the electron beam irradiating the storage portion of the film forming source can be deflected. By utilizing the deflected trajectory, the degree of freedom when controlling the trajectory of the electron beam increases, and it becomes easy to continuously irradiate the melt in the film forming source with the electron beam. Here, the deflected trajectory is a trajectory in a case where a proceeding direction of the electron beam which is just emitted from the electron gun and a proceeding direction of the electron beam which is about to be incident on an irradiated object are different from each other. Specifically, as the trajectory of the electron beam from the emission to the incidence, the deflected trajectory is not a straight trajectory but a curved trajectory. The trajectory of the electron beam can be deflected by, for example, a magnetic field.

In the thin film manufacturing device of the present invention, the tilt mechanism may support the film forming source during the film formation to maintain the film formation posture of the film forming source. However, in addition to the tilt mechanism, it is preferable that the thin film manufacturing device of the present invention further include a film forming source supporting mechanism configured to support the film forming source to maintain the film formation posture. The film forming source supporting mechanism is not limited as long as it can maintain the film formation posture of the film forming source. For example, the film forming source supporting mechanism may be a mount having a horizontal upper surface. The film formation posture is easily maintained by arranging the film forming source on the mount. By providing the film forming source supporting mechanism separately from the tilt mechanism, the film formation posture of the film forming source can be maintained without applying a load to the tilt mechanism during the film formation.

A material constituting the film forming source is not limited. However, carbon is preferable since its reactivity with the film formation material is low. To be specific, it is preferable that the film forming source be a carbon crucible. Since the carbon crucible tends to cause the crack damage and is expensive, applying the present invention to the carbon crucible is significant.

The film formation material used in the present invention is not limited, but silicon is preferable. Unlike common metal materials, silicon expands when it solidifies from the melt state by cooling. Therefore, the crack damage of the film forming source tends to occur. On this account, applying the present invention when manufacturing the thin film using silicon as the film formation material is extremely significant.

It is preferable that the thin film manufacturing device of the present invention further include a melt reservoir including a recess on an upper surface thereof to receive the melt discharged from the storage portion by the tilting of the film forming source. With this, the film formation material discharged from the film forming source can be recycled without discarding it.

Moreover, it is preferable that: the recess of the melt reservoir be a horizontally laid rod-shaped recess; the melt solidify in the recess to form a rod-shaped body made of the film formation material; the thin film manufacturing device further include a material feed system configured to feed the rod-shaped body to above the film forming source; and a tip end of the rod-shaped body fed by the material feed system be irradiated with the electron beam. To be specific, by irradiating the tip end of the rod-shaped body fed by the material feed system with the electron beam, the tip end melts, and the melt of the film formation material is generated. The generated melt is supplied to the storage portion of the film forming source. Thus, the film formation material is replenished to the film forming source. With this, the film formation material discharged from the film forming source can be supplied to the film forming source again, and the film formation can be performed again. Therefore, the use efficiency of the film formation material can be improved. The horizontally laid rod-shaped recess is a recess that is a column-like space, such as a cylinder or a prism, arranged such that a side surface thereof is substantially horizontal and an upper surface thereof opens.

Further, to solve the above problems, a thin film manufacturing method of the present invention includes: a thin film forming step of irradiating a film formation material in a storage portion of a film forming source maintained in a film formation posture with an electron beam to melt the film formation material, generate a melt, evaporate the film formation material, and form the thin film on a substrate in vacuum; and a melt discharging step of continuously irradiating the melt in the storage portion with the electron beam after the thin film forming step to maintain a state of the melt in the storage portion and tilting the film forming source from the film formation posture to an inclined posture to discharge the melt from the storage portion, the inclined posture being a posture by which the storage portion is not able to hold the melt.

It is preferable that in the thin film manufacturing method of the present invention, the melt discharged in the melt discharging step be received by a melt reservoir to be recovered as a rod-shaped body of the film formation material, the melt reservoir including a horizontally laid rod-shaped recess on an upper surface thereof.

Moreover, it is preferable that the thin film manufacturing method of the present invention further include: a second film formation preparing step of putting the film forming source back to the film formation posture after the melt discharging step, supplying the film formation material to the storage portion of the film forming source, and providing the rod-shaped body at a material feed system; a second thin film forming step of irradiating the film formation material in the storage portion of the film forming source maintained in the film formation posture with the electron beam after the second film formation preparing step to melt the film formation material, evaporate the film formation material, and form the thin film again on the substrate in vacuum; and a material supplying step of, while moving a tip end of the rod-shaped body to above the film forming source by the material feed system, irradiating the tip end with the electron beam in the second thin film forming step to melt the tip end and supply the obtained melted material to the film forming source.

The thin film manufacturing method of the present invention may be a method for manufacturing a thin film containing silicon, including: a thin film forming step of irradiating the silicon that is a film formation material in a recess of a crucible with an electron beam to melt the silicon, generate a melt, evaporate the film formation material, and form the thin film containing the silicon on a substrate in vacuum; and a melt discharging step of continuously heating the melt in the recess after the thin film forming step to maintain a state of the melt in the recess and tilting the crucible to discharge the melt from the recess.

Silicon expands when it solidifies from the melt state by cooling. Therefore, if silicon is left in the crucible, the crack damage of the crucible tends to occur. In accordance with the above configuration, the tilting is performed while surely maintaining the melt state by continuously heating the melt during the tilting. Therefore, substantially the entire amount of silicon can be discharged from the crucible, the solidification of silicon in the crucible can be prevented, and the crack damage of the crucible by the solidification of silicon can be avoided.

### Advantageous Effects of Invention

In accordance with the present invention, the film formation material can be discharged from the crucible while maintaining the melt state of the film formation material in the crucible by continuously irradiating the film formation material with the electron beam. Therefore, the remaining of the film formation material in the crucible can be suppressed. On this account, it is possible to avoid the crack damage of the crucible which may be caused by the solidification of the film formation material in the crucible, and the crucible can be used repeatedly. As a result, the film formation can be performed stably at low cost.

### BRIEF DESCRIPTION OF DRAWINGS

FIG. 1 are schematic diagrams each showing the structure of film forming apparatus that is one example of an embodiment of the present invention. FIG. 1(a) is a diagram showing a state where a film is being formed. FIG. 1(b) is a diagram showing a state where a melt is being discharged. FIG. 1(c) is a diagram showing a state where the discharge of the melt is completed.

FIG. 2 are schematic diagrams showing specific examples of a storage portion of an evaporation crucible.

FIG. 3 is a schematic diagram showing a state where an electron gun emits a main electron beam and supply electron beams in a distributed manner.

FIG. 4 is a schematic diagram showing one example of a method for experimentally confirming a trajectory of the electron beam.

FIG. 5 are schematic diagrams showing a process of determining control of the position of the evaporation crucible when the evaporation crucible tilts.

FIG. 6 is a schematic diagram showing one example of a rotation detecting unit of the evaporation crucible.

FIG. 7 are schematic diagrams showing one example of control of the trajectory of the electron beam.

### DESCRIPTION OF EMBODIMENTS

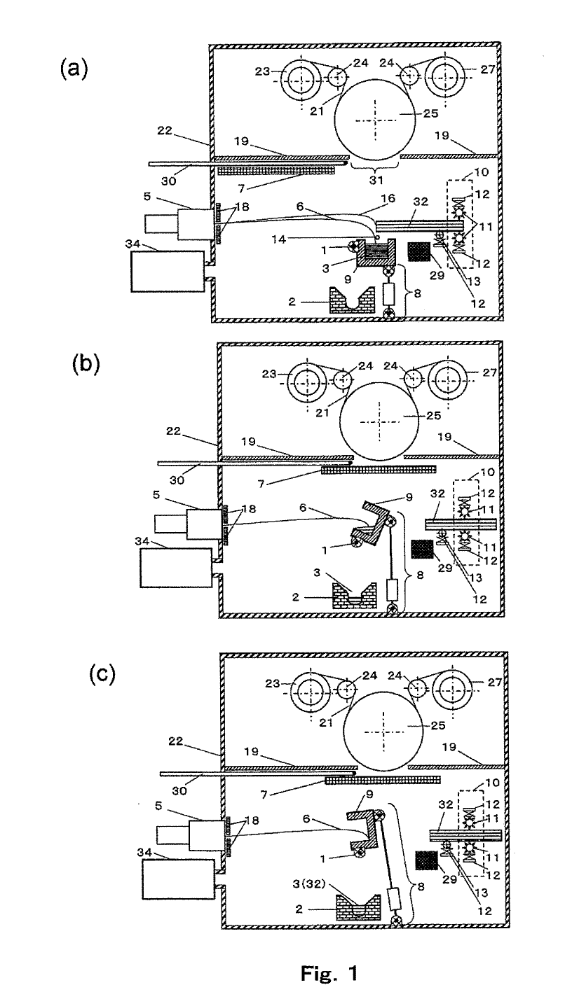

FIG. 1 are diagrams each schematically showing the structure of film forming apparatus that is one example of an embodiment of the present invention.

FIG. 1(a) schematically shows the film forming apparatus during film formation. FIG. 1(b) schematically shows the film forming apparatus when a film forming source is tilted after the completion of the film formation to discharge a melt in the film forming source. FIG. 1(c) schematically shows the film forming apparatus when the film forming source is inclined at a maximum inclination angle, and the discharge of the melt from the film forming source is substantially completed.

An exhaust pump 34 evacuates air from a vacuum chamber 22. An evaporation crucible (film forming source) 9 is arranged in the vacuum chamber 22. A deposition material 3 is held in a recess (storage portion) of the evaporation crucible 9. The deposition material 3 becomes the melt by the irradiation of a main electron beam 6 from an electron gun 5. A part of the melt evaporates and reaches a substrate 21 to form a thin film. Each of various materials, such as resin, metal, and ceramic, can be used as the material of the substrate depending on the purpose and effect of the thin film, and each of various shapes, such as a film shape, a plate shape, and a block shape, can be used as the shape of the substrate. In the case of using an elongated substrate, such as a resin film or a metal foil, in a roll shape, while the substrate is being fed by a substrate feed system to pass through a predetermined film formation position, the thin film can be formed on the surface of the substrate. Therefore, it is possible to provide the thin film manufacturing device which excels in productivity. The film formation position is determined by, for example, the position of an opening 31 of a shielding plate 19. A film formation step starts or terminates by, for example, opening or closing a plate-shaped shutter 7 provided between the evaporation crucible 9 and the opening 31 of the shielding plate 19.

One example of the entire configuration of the film forming apparatus configured to form the thin film on the surface of the elongated substrate will be explained. The vacuum chamber 22 is a pressure-resistant container-like member having an internal space. The internal space accommodates a pull-out roller 23, feed rollers 24, a can 25, a take-up roller 27, the evaporation crucible 9, a melt reservoir 2, a material supply unit 10, the shielding plate 19, and a material gas introduction tube 30. The pull-out roller 23 is a roller-like member provided above the can 25 in a vertical direction so as to be rotatable about a shaft center thereof. The substrate 21 having an elongated band shape winds around the surface of the pull-out roller 23. The pull-out roller 23 feeds the substrate 21 toward the feed roller 24 closest to the pull-out roller 23. The feed roller 24 is a roller-like member provided to be rotatable about a shaft center thereof The feed roller 24 guides to the can 25 the substrate 21 having been fed from the pull-out roller 23, and the substrate 21 is finally guided to the take-up roller 27. The can 25 is a roller-like member provided to be rotatable about a shaft center thereof. A cooling unit, not shown, is provided inside the can 25. Used as the cooling unit is, for example, a cooler configured to perform cooling by circulation of cooling water. When the substrate 21 travels a peripheral surface of the can 25, according to need, material particles from the evaporation source react with a material gas introduced from the material gas introduction tube 30 to be deposited on the surface of the substrate 21. Thus, the thin film is formed on the surface of the substrate 21. The take-up roller 27 is a roller-like member provided above the can 25 in the vertical direction so as to be rotated by a drive unit, not shown. The take-up roller 27 takes up and holds the substrate 21 on which the thin film is formed.

The evaporation source is a container-like member which is provided under a vertically lowermost portion of the can 25 in the vertical direction and whose vertically upper portion opens. Specifically, the evaporation source is constituted by the evaporation crucible, and the deposition material (film formation material) 3 is stored in the evaporation crucible 9. The electron gun 5 is provided in the vicinity of the evaporation crucible 9. The deposition material 3 in the evaporation crucible 9 is heated by the electron beam 6 emitted from the electron gun. Thus, the deposition material 3 becomes the melt, and the melt evaporates. The vapor of the deposition material moves upward in the vertical direction through the opening 31 to reach the vertically lowermost portion of the can 25. Here, the deposition material adheres to the surface of the substrate 21 to form the thin film.

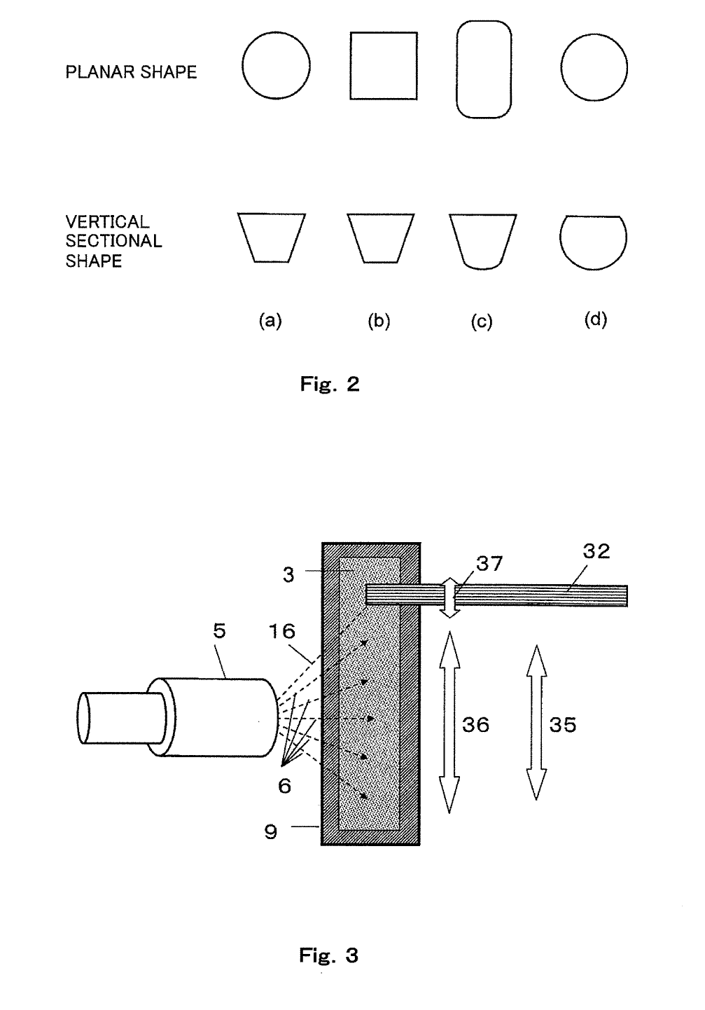

Each of crucibles of various shapes, such as a circular shape, an oval shape, a rectangular shape, and a doughnut shape, can be used as the evaporation crucible 9 depending on the intended film formation. Examples of the material constituting the evaporation crucible 9 are oxides, such as alumina, magnesia, and calcia, and refractories, such as boron nitride and carbon. For example, in continuous vacuum deposition, such as a take-up type, which excels in mass productivity, in order to uniformize the film thickness in a width direction, it is effective to use a rectangular crucible which is wider than a film formation width on the surface of the substrate. The recess (storage portion) for storing the deposition material is formed on the upper surface of the evaporation crucible 9. An opening is formed on a vertically upper portion of the storage portion such that the deposition material can evaporate upward. FIG. 2 show specific examples of the top views and vertical sectional views of the storage portion of the evaporation crucible 9. In FIG. 2, an upper row shows the top views, and a lower row shows the vertical sectional views. The vertical sectional shape of the storage portion may be any shape, such as a rectangular shape, a trapezoidal shape, a drum shape, or a rectangular, trapezoidal, or drum shape whose bottom is rounded. Among these, the vertical sectional shape of the storage portion is desirably an inverted trapezoidal shape (FIGS. 2(a) and 2(b)) or an inverted trapezoidal shape whose bottom is rounded (FIG. 2(c)). This is because the deposition material can be uniformly melted in the storage portion.

In addition to the evaporation crucible 9, an evaporation mechanism includes the electron gun 5 that is a generation source of the main electron beam 6 for heating, melting, and evaporating the deposition material 3. The evaporation mechanism further includes a tilt mechanism 8 and the melt reservoir 2. The tilt mechanism 8 tilts the evaporation crucible 9 after the film formation. Thus, the melt of the deposition material 3 held in the evaporation crucible 9 is discharged toward the melt reservoir 2. In a case where the main electron beam 6 is stopped and the evaporation crucible is tilted, the deposition material 3 starts solidifying in the evaporation crucible 9 during the tilting. Therefore, the stress tends to occur due to the solidified deposition material. Moreover, rapidly performing such tilting for the purpose of discharging the melt before the deposition material solidifies brings a significant risk, such as scattering of the melt, especially in the case of a large crucible. Here, in the present invention, the deposition material 3 in a melt state is discharged from the evaporation crucible 9 while suppressing the solidification of the deposition material 3 in the evaporation crucible 9 by continuously irradiating the deposition material 3 in the evaporation crucible 9 with the main electron beam 6 during the tilting after the film formation. Thus, it is possible to prevent the deposition material 3 from remaining in the evaporation crucible 9. Therefore, it is possible to prevent the crack damage of the evaporation crucible 9 by the solidification of the deposition material 3 in the evaporation crucible 9. This will be described later in detail.

A region where the material particles from the evaporation crucible 9 contact the substrate 21 is limited to only the opening 31 by the shielding plate 19. The material gas introduction tube 30 is provided depending on a constituent element of the intended thin film. The material gas, such as oxygen or nitrogen, is supplied through the material gas introduction tube 30. The material gas introduction tube 30 is a tubular member having one end located above the evaporation crucible 9 in the vertical direction and in the vicinity of the opening 31 and the other end connected to a material gas supply unit (not shown) provided outside the vacuum chamber 22. With this, the thin film containing, as a major component, oxide, nitride, or oxynitride of the material emitted from the evaporation source is formed on the surface of the substrate 21. Examples of the material gas supply unit are a gas bomb and a gas generator. The exhaust pump 34 is provided outside the vacuum chamber 22. The exhaust pump 34 adjusts the inside of the vacuum chamber 22 such that the inside becomes a pressure-reduced state suitable for thin film formation.

To stably continue the film formation for a long period of time, it is preferable that the film formation be performed while replenishing the melted deposition material to the evaporation crucible 9. In this case, after a solid supply material, such as a rod-shaped body 32, is slowly moved to the upper side of the evaporation crucible 9, a tip end of the rod-shaped body 32 is melted to generate a liquid droplet 14 of the deposition material. The liquid droplet 14 can be dropped to the evaporation crucible 9. By gradually sending the rod-shaped body 32 in accordance with the melting of the tip end thereof, the melted deposition material can be continuously replenished to the evaporation crucible 9. To melt the tip end of the rod-shaped body 32, the tip end may be irradiated with the supply electron beam 16. An electron gun configured to emit the supply electron beam 16 may be provided separately from the electron gun 5 configured to emit the main electron beam 6 irradiating the evaporation crucible 9. However, as shown in FIG. 1, the electron gun 5 can emit both the main electron beam 6 and the supply electron beam 16. FIG. 3 is a top view schematically showing a state where the electron gun 5 emits both the main electron beam 6 and the supply electron beam 16 in a distributed manner. Herein, it is desirable that the main electron beam 6 scan in a substrate width direction such that the main electron beam 6 irradiates the film formation material 3 in the evaporation crucible 9 as uniformly as possible. A range shown by reference sign 36 in FIG. 3 is a scan range of the main electron beam 6 in the substrate width direction. A range shown by reference sign 35 in FIG. 3 is the film formation width on the surface of the substrate. To uniformize the film thickness in the substrate width direction, it is preferable that the main electron beam scan range 36 be set to be wider than the film formation width 35. Moreover, it is desirable that an irradiation range 37 of the supply electron beam 16 above the evaporation crucible 9 and a dropping position of the liquid droplet generated by melting the rod-shaped body 32 (a position under the tip end of the rod-shaped body 32 in the vertical direction) be set to be located on an outer side of the main electron beam scan range 36. With this, it is possible to reduce influences on the film formation by changes in temperature of the melt and vibrations of the surface of the melt, which may occur by the replenishment of the material to the evaporation crucible 9.

The electron gun 5 is arranged such that the electron beam can irradiate the inside of the vacuum chamber 22. A straight gun or a deflection gun can be used as the electron gun 5. Among these, the combination of the straight gun and a deflection coil 29 is especially preferable since it is high in the degree of freedom of design for controlling the trajectory of the beam or the tilting of the crucible. This combination can form both a straight trajectory and a deflected trajectory as the trajectory of the electron beam. The deflection coil 29 is arranged in the vicinity of the evaporation crucible 9. The deflection coil 29 generates a magnetic field to deflect the trajectory of the electron beam. Moreover, the deflection coil 29 can change the trajectory of the electron beam with time by changing the magnitude of the magnetic field. For example, the electron gun is provided horizontally and incorporates a magnet coil (not shown). An emission angle of the electron beam from the electron gun can be adjusted by the magnet coil. An accelerating voltage of the electron beam depends on the type of the deposition material 3 and a film formation rate. However, the accelerating voltage of the electron beam is, for example, −30 kV, and desirably −8 to −40 kV. Electric power of the main electron beam 6 is preferably about 5 to 100 kW. When the electric power of the main electron beam 6 is lower than 5 kW, the amount of evaporation may become inadequate. When the electric power of the main electron beam 6 exceeds 100 kW, material scattering or bumping may occur in the evaporation crucible 9.

The emission angle of the main electron beam 6 from the electron gun 5 during the film formation is, for example, +5 degrees with respect to the horizontal plane. An incidence angle of the main electron beam 6 on the evaporation crucible 9 during the film formation is preferably such that the direction of the main electron beam 6 is closer to the vertical direction. For example, the incidence angle of the main electron beam 6 is 60 degrees with respect to the horizontal plane that is the surface of the melt. By setting the emission angle of the main electron beam 6 to the positive angle with respect to the horizontal plane, the incidence angle of the main electron beam 6 on the evaporation crucible 9 can be designed such that the direction of the main electron beam 6 is closer to the vertical direction in the limited space of the vacuum chamber 22. Moreover, a deposition shield wall 18 is provided between the electron gun 5 and the vacuum chamber 22 except for a portion through which the electron beam passes. With this, it is possible to suppress the contamination of the inside of the electron gun 5 by the vapor from the evaporation crucible 9.

During the film formation, the evaporation crucible 9 takes a film formation posture (FIG. 1(a)). After the shutter 7 is closed and the film formation step is terminated, the emission of the supply electron beam 6 is stopped, and the rod-shaped body 32 is move backward. Then, the evaporation crucible 9 is gradually tilted in a direction in which an electron beam emission surface of the electron gun 5 is located. The tilting is performed by the tilt mechanism 8 by utilizing a force transmitted mechanically by using a motor, a cylinder, or the like as a power source. In FIG. 1(b), the evaporation crucible 9 takes a posture which is in the middle of the tilting. In the present invention, to prevent the crack damage of the evaporation crucible 9, the crucible is tilted up to an angle at which substantially the entire amount of film formation material can be discharged from the crucible. To be specific, to prevent the film formation material from remaining at corner portions of a storage space in the crucible when the crucible is inclined, the crucible is tilted up to an inclination angle at which the storage space in the crucible cannot hold the melt. In FIG. 1(c), the evaporation crucible 9 takes an inclined posture, that is, the evaporation crucible 9 is inclined at a maximum inclination angle at which the storage space in the crucible cannot hold the melt. As with the crucible shown in FIG. 1, in a case where the inner wall surface of the crucible is perpendicular to the horizontal plane, the maximum inclination angle may be larger than 90 degrees. In contrast, as shown in FIGS. 2(a) to 2(c), in a case where the inner wall surface of the crucible is not perpendicular to the horizontal surface, and the area of an inner bottom surface of the crucible is smaller than the area of the opening of the crucible, substantially the entire amount of film formation material can be discharged from the crucible even if the maximum inclination angle is smaller than 90 degrees.

As shown in FIGS. 1(b) and 1(c), even in the process of tilting the evaporation crucible 9 and discharging the film formation material, the main electron beam 6 continuously irradiates the deposition material 3 in the crucible. With this, the deposition material 3 in the crucible can maintain the melt state even after the film formation. Therefore, the deposition material 3 is efficiently discharged from the crucible by the tilting of the crucible, and it is possible to suppress the remaining of the deposition material 3 in the crucible when the tilting is completed.

In the present invention, while the evaporation crucible 9 tilts up to the maximum inclination angle, the deposition material 3 in the evaporation crucible 9 is continuously irradiated with the main electron beam 6. To achieve this, two types of methods can be used. A first method is to: irradiate the deposition material 3 in the crucible with the main electron beam 6 during the tilting while maintaining the trajectory of the electron beam at the time of the film formation; and continuously irradiate the deposition material 3 in the crucible with the main electron beam 6 by controlling the position of the evaporation crucible 9 when the evaporation crucible 9 tilts (that is, by controlling the trajectory of the evaporation crucible 9 when the evaporation crucible 9 tilts) (FIG. 1). In this case, the position of a rotation axis that is the center of the tilting of the crucible is located outside the crucible. A second method is to continuously irradiate the deposition material 3 in the crucible with the main electron beam 6 by controlling and changing the trajectory of the electron beam during the tilting of the crucible (FIG. 7). Specifically, this method can be carried out by detecting the inclination angle of the evaporation crucible 9 and modifying the trajectory of the main electron beam 6 based on the detected inclination angle.

In these methods, to continuously irradiate the deposition material 3 in the crucible with the main electron beam 6 during the tilting of the evaporation crucible 9, it is necessary to accurately grasp the trajectory of the main electron beam 6. To grasp the trajectory of the electron beam, two methods, that is, calculation and actual measurement can be used. Various methods can be used as the calculation and the actual measurement. Examples will be described below.

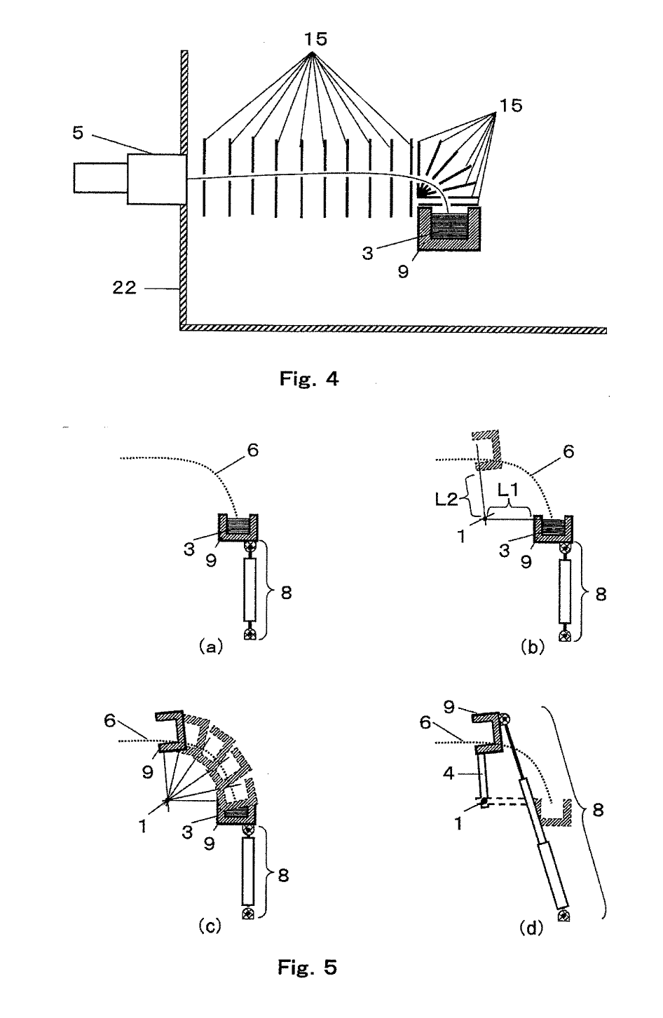

In a method for grasping the trajectory of the electron beam by the calculation, a deflection magnetic field by the deflection coil is calculated, and the trajectory of the electron beam is then calculated. The calculation of the deflection magnetic field can be performed by a typical magnetic field calculation using a finite element method using, as parameters, the current of the deflection coil, the turns of the deflection coil, the shape of an iron core, the shape of a pole piece, and the like. Moreover, magnetic field intensity can be directly measured by, for example, a 3D gaussmeter. Based on magnetic field distribution data obtained as above, the trajectory of the electron beam can be calculated by calculation of Lorentz force using, as parameters, the accelerating voltage and an initial emission direction. To experimentally confirm the trajectory of the electron beam, first, the electron beam irradiates a predetermined position on the evaporation crucible. After the irradiation of the electron beam is stopped once, an appropriate number of thin plates 15 are provided in a range through which the electron beam passes. Then, by irradiating the position with the electron beam again, holes are formed at electron beam irradiation positions on the thin plates. Thus, a curved line formed by connecting the positions of the holes shows the trajectory of the electron beam (FIG. 4).

In the present embodiment, the electron gun 5 is provided horizontally. After the electron gun 5 emits the main electron beam 6 substantially horizontally, the trajectory of the main electron beam 6 is deflected by the deflection coil 29 provided in the vicinity of the evaporation crucible 9 such that the direction of the main electron beam 6 becomes closer to a direction perpendicular to the surface of the melt. In this case, the deposition material 3 in the crucible can be continuously irradiated with the main electron beam 6 by controlling the position of the evaporation crucible 9 when the evaporation crucible 9 tilts while maintaining the trajectory of the main electron beam 6 at the time of the film formation (that is, by the above-described first method).

FIG. 5 schematically show the process of determining the control of the position of the evaporation crucible when the evaporation crucible tilts. FIG. 5(a) shows the trajectory of the main electron beam 6 irradiating the deposition material 3 in crucible during the film formation and at the time of the termination of the film formation. In FIG. 5(b), a rotational center 1 that is the center of the tilting of the evaporation crucible 9 is arranged outside the crucible and on a side where the electron beam emission surface is located. In addition, the rotational center 1 is the same in height as the surface of the melt in the crucible. The rotational center 1 is a point where a distance L1 to the crucible before the tilting is equal to a distance L2 to the crucible (shown by broken lines in FIG. 5(b)) after the tilting. Before determining the rotational center 1, as shown in FIG. 5(c), the trajectory of the tilting of the evaporation crucible and the trajectory of the main electron beam 6 are overlapped each other to confirm that these trajectories coincide with each other. The rotational center determined on the drawing as above can be determined as an actual mechanical element by, for example, an arm 4 connected to the evaporation crucible 9 as shown in FIG. 5(d). The tilt mechanism 8 configured to generate a thrust force in the tilting is in a state shown in FIGS. 5(a) to 5(c) before the tilting and is in an extended and inclined state shown in FIG. 5(d) after the tilting. By the operation of the tilt mechanism, the evaporation crucible 9 performs the tilting using the rotational center 1 as a rotation axis. Thus, the trajectory of the evaporation crucible 9 can be controlled when the evaporation crucible 9 tilts.

It is desirable that the rotational center 1 and the arm 4 be provided outside the width of the storage portion of the evaporation crucible so as not to become obstacles to the discharge of the melt from the crucible. It is further desirable that the position of the rotation axis be finely adjusted by an actual tilting test. Depending on the deflected trajectory of the electron beam, it may be desirable to provide a mechanism in which the position of the rotation axis moves in accordance with the inclination angle of the crucible. Specifically, the position of the evaporation crucible during the tilting can be more precisely controlled by displacing the position of the rotational center using, for example, a cam mechanism during the tilting or by changing the distance between the evaporation crucible and the rotational center by extending or retracting the arm 4 during the tilting.

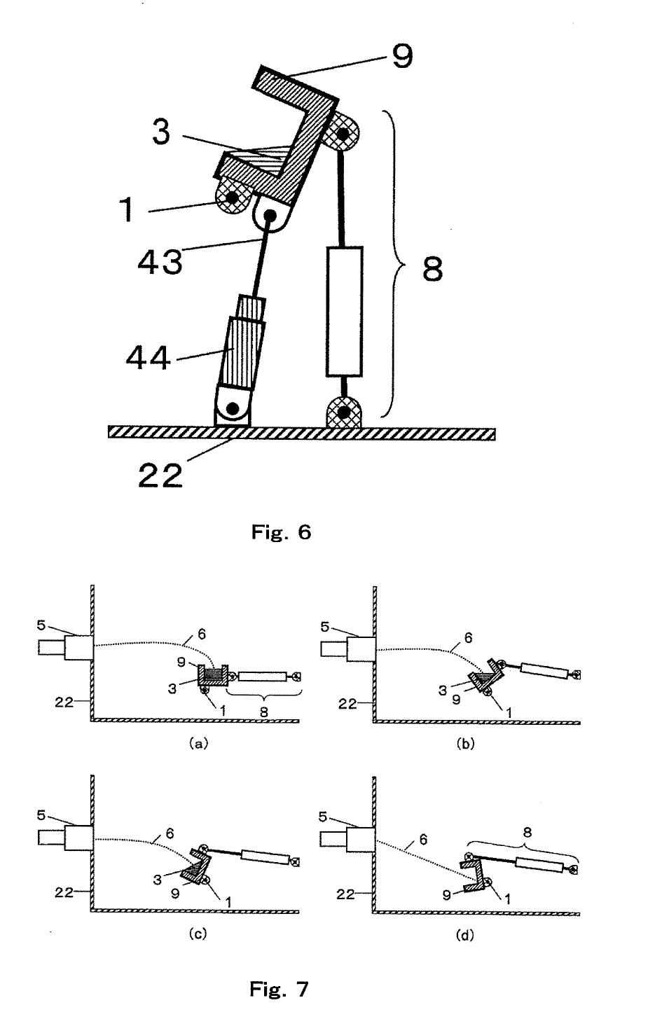

In accordance with the second method for controlling the trajectory of the electron beam, an inclination detecting unit and a trajectory modifying unit are provided in the vacuum chamber 22. The inclination detecting unit detects the inclination angle of the evaporation crucible 9, and the trajectory modifying unit modifies the trajectory of the main electron beam 6 based on the detected inclination angle. For example, a rotary encoder can be used as the inclination detecting unit. As shown in FIG. 6, a tilting movement can be converted into a straight movement by using, for example, a link rod 43, and the inclination angle can be detected by using a differential transformer 44.

The trajectory modifying unit is, for example, a combination of the magnet coil (not shown) incorporated in the electron gun 5 and the deflection coil 29 provided in the vicinity of the evaporation crucible 9. The trajectory of the electron beam can be modified by changing current values of these coils. The current value of the magnet coil incorporated in the electron gun 5 is programmed in order to mainly change the emission direction of the electron beam depending on the inclination angle of the evaporation crucible 9, the inclination angle being detected by the inclination detecting unit. The current value of the deflection coil 29 provided in the vicinity of the evaporation crucible 9 is programmed in order to mainly change the amount of deflection of the electron beam in the vicinity of the evaporation crucible 9 depending on the inclination angle of the evaporation crucible 9, the inclination angle being detected by the inclination detecting unit.

FIG. 7 schematically show a specific example in which the trajectory of the electron beam is controlled by the above-described second method to be changed with time. FIG. 7(a) shows a state in the film formation, each of FIGS. 7(b) and 7(c) shows a state during the tilting, and FIG. 7(d) shows a state when the tilting is completed. In FIG. 7(a), the electron gun 5 is provided horizontally and emits the main electron beam 6 slightly upward with respect to the horizontal plane during the film formation, and an incidence direction of the main electron beam 6 is deflected by the deflection coil 29 (not shown), provided in the vicinity of the evaporation crucible 9, to be closer to the direction perpendicular to the surface of the melt. In FIGS. 7(b) to 7(d), as the evaporation crucible 9 tilts, the emission direction of the main electron beam 6 is changed to the horizontal direction or a downward direction with respect to the horizontal direction, and the coil current of the deflection coil 29 is decreased to decrease the amount of deflection of the main electron beam 6 during the tilting. With this, the deposition material 3 in the crucible is continuously irradiated with the main electron beam 6. To change the amount of deflection of the main electron beam, the position of the magnet coil may be suitably moved.

FIG. 7 show a case where the trajectory of the electron beam is gradually changed from the deflected trajectory to the straight trajectory. However, the present invention is not limited to this. For example, the control of the trajectory of the electron beam in the present invention includes a case where the straight trajectory of the electron beam is maintained but the emission angle of the electron beam is changed.

Specific examples of numerical values adoptable in FIG. 7 will be described below. During the film formation, the emission angle of the main electron beam having the accelerating voltage of −30 kV is +3 to +5 degrees, the current of the deflection coil is 0.3 to 0.5 ampere, and the magnetic field in the vicinity of the evaporation crucible is about 20 to 35 gausses. At the time of the completion of the tilting, the emission angle is −5 to −15 degrees, the current of the deflection coil is 0 to 0.2 ampere, and the magnetic field in the vicinity of the evaporation crucible is about 0 to 15 gausses.

The melt discharged from the evaporation crucible 9 by the tilting of the evaporation crucible 9 is recovered by the melt reservoir 2. The position of the melt reservoir 2 may be fixed. However, it is more desirable that the position of the melt reservoir 2 move in accordance with the tilting of the evaporation crucible 9 and the movement of the position of the discharge of the melt. Examples of the shape of the melt reservoir 2 are a round shape, an oval shape, and a box shape. The shape of the melt reservoir 2 is suitably selected in consideration of, for example, the shape of the evaporation crucible 9, spatial restriction in the device, and whether or not the recovered deposition material is recycled. Especially, in the case of solidifying the recovered melt and using the melt as the supply material for the next film formation, it is effective to recover the melt in the melt reservoir 2 having, on its upper surface, a horizontally laid rod-shaped cutout (recess). With this, a rod-shaped supply material can be obtained from the recovered melt. Moreover, an upper portion of the melt reservoir is formed in a funnel shape. With this, the melt does not spill out, and the recovery of the material and rod-shaped solidification can be realized further easily.

Examples of the material constituting the melt reservoir 2 are: metals, such as water-cooled copper hearth, iron, nickel, molybdenum, tantalum, and tungsten; alloys of these metals; oxides, such as alumina, magnesia, and calcia; and refractories, such as boron nitride and carbon.

It is desirable that the melt reservoir 2 be constituted by the water-cooled copper hearth or a mass of metal, such as iron, nickel, molybdenum, tantalum, or tungsten, having a high heat capacity. With this, it is possible to prevent the recovered melt from reacting with the melt reservoir. Therefore, it is possible to prevent the damage of the melt reservoir, and the deposition material can be separated and recovered from the melt reservoir to be recycled.

Especially, in a case where the cutout of the melt reservoir is formed in a rod shape, the rod-shaped body 32 made of the deposition material can be obtained by the solidification of the melt in the melt reservoir. In a case where the melt reservoir is configured to be splittable, the rod-shaped body 32 can be easily taken out of the melt reservoir.

The rod-shaped body 32 can be put, melted, and recycled in the evaporation crucible 9 in the next or subsequent film formation utilizing the thin film manufacturing device of the present invention. Moreover, the shape characteristic of the rod-shaped body 32 is utilized, that is, the rod-shaped body 32 can be recycled by: arranging the tip end of the rod-shaped body 32 above the evaporation crucible 9 in the film formation; irradiating the tip end with the supply electron beam 16 to melt the tip end; and dropping the liquid droplet 14 of the deposition material onto the evaporation crucible 9.

In the latter case, it is preferable to arrange an irregular inexpensive deposition material in the evaporation crucible 9 before starting the film formation and recycle the rod-shaped body when replenishing the deposition material to the crucible after starting the film formation, the rod-shaped body being formed in the melt reservoir. With this, the film formation can be stably performed for a long period of time without purchasing an expensive rod-shaped material.

The rod-shaped body 32 obtained by solidifying the deposition material in the melt reservoir 2 is fed by the material feed system 10 to above the evaporation crucible 9. The tip end of the fed rod-shaped body is arranged above the evaporation crucible 9. The tip end of the rod-shaped body 32 is irradiated with the supply electron beam 16 emitted from the electron gun to liquefy. Thus, the tip end becomes the liquid droplet 14, and the liquid droplet 14 is dropped to the evaporation crucible 9.

Depending on the type of the deposition material, the shape of the rod-shaped body, and the feed speed, the electric power of the supply electron beam 16 is preferably about 5 to 100 kW. When the electric power is lower than 5 kW, a melting rate of the rod-shaped body may not be adequate. When the electric power exceeds 100 kW, the melting rate of the rod-shaped body may be too high, and the liquid droplet 14 from the rod-shaped body may drop just outside the evaporation crucible.

The supply electron beam 16 to the rod-shaped body 32 may be emitted from a dedicated supply electron gun, or the electron gun 5 configured to emit the main electron beam 6 may also emit the supply electron beam. In a case where the electron gun 5 emits both beams, the deflection of the trajectory of the beam is controlled by the magnetic field. The deflection of the trajectory of the beam is controlled by controlling the magnetic field generated by the magnet coil incorporated in the electron gun 5 and the deflection coil 29 provided in the vicinity of the evaporation crucible 9. Specifically, the deflection of the trajectory of the beam is controlled by controlling the intensity and time length of the current flowing through each of the magnet coil and the deflection coil that are electromagnets, and the irradiation position of the main electron beam and the irradiation position of the supply electron beam can be separated by changing the currents of the coils step-by-step.

The electron beams emitted from the electron gun are deflected by the deflection magnetic field generated by the magnet coil and the deflection coil. Most of the beams irradiate the melt in the evaporation crucible 9 as the main electron beam 6, and a part of the beams irradiate, as the supply electron beam 16, the tip end of the rod-shaped body which is being fed by the material feed system 10. With this, both the main electron beam and the supply electron beam can be emitted from the electron gun 5, and this can reduce the device cost.

A feed unit constituting the material feed system 10 is not especially limited. One example of the feed unit is a feed roller. Specifically, chuck rollers 11 each having projections are arranged above and under the rod-shaped body 32, respectively. With this, the chuck rollers 11 can sandwich the rod-shaped body 32 from above and under the rod-shaped body 32 to feed the rod-shaped body 32. Depending on the material and shape of the rod-shaped body 32 and a pull-out rate, sandwiching pressure is, for example, 3 to 50 kgf.

When the sandwiching pressure is too low, slip may occur, and smooth feed may not be performed. In contrast, when the sandwiching pressure is too high, the rod-shaped body may deform or break. In many cases, the rod-shaped body 32 is not formed in a geometric shape, such as a prism, and has an irregular side surface. Therefore, it is difficult to stabilize the sandwiching by the chuck rollers 11. Here, it is desirable that a sandwiching mechanism including the chuck rollers and the like be provided with a cushioning mechanism 12 including a spring and the like. Moreover, it is possible to adopt a system in which a chuck unit as the feed unit other than the chuck roller fixes the rod-shaped body and slides to feed the rod-shaped body.

The material feed system 10 is provided with a feed guide 13 according to need. The rod-shaped body 32 is fed along the feed guide 13. The feed guide 13 can be constituted by a roller, a fixed post, a fixed guide, or the like. By using the feed guide 13, meandering of the rod-shaped body 32 can be prevented, breakage of the rod-shaped body 32 by the stress whose fulcrum point is the sandwiching mechanism can be prevented, and a drive load of the feed unit can be reduced. The feed guide 13 may be fixed but may be configured to be movable by, for example, the cushioning mechanism 12. In a case where the feed guide 13 is configured to be movable, a following capability with respect to the change in position of the rod-shaped body 32 improves, and this can further stabilize the feeding of the rod-shaped body. The feed guide 13 may be omitted in a case where there is no room for the feed guide 13 due to, for example, limitations of the shape of the device.

It is preferable that the rod-shaped body be heated by a heating mechanism when it is fed by the material feed system. With this, water adsorption to the rod-shaped body can be prevented, the evaporation rate of the material from the evaporation crucible can be maintained constant, and high-quality film formation can be realized.

As above, in accordance with the thin film manufacturing device of the present invention, since the thin film can be formed on the substrate, and substantially the entire amount of deposition material remaining in the evaporation crucible can be removed after the formation of the thin film, the damage of the crucible can be prevented, and the crucible can be stably and repeatedly used.

The foregoing has explained a case where the film is formed on the substrate provided along the cylindrical can. However, the present invention is not limited to this. For example, the film formation by oblique incidence can be carried out with respect to the substrate travelling linearly. In accordance with the film formation by the oblique incidence, a thin film containing microspaces therein can be formed by a self-shadowing effect. Therefore, the film formation by the oblique incidence is effective to form, for example, high C/N magnetic tapes and battery negative electrodes having excellent cycle characteristic.

In accordance with the present invention, an elongated battery polar plate can be obtained by using a band-shaped copper foil as the substrate, evaporating silicon from the evaporation crucible, and supplying silicon to the evaporation crucible. Moreover, an electrochemical capacitor polar plate can be obtained by a method similar to the above.

In these cases, for example, 6 kg of #441 grade metal silicon is filled in a carbon crucible, and the inside of the crucible is irradiated with 50 kW electron beam emitted from the electron gun 5. Thus, an elongated silicon thin film can be formed. A tip end of a prism-shaped supply silicon rod having a cross-sectional area of 30 square centimeters is arranged above the crucible and is irradiated with a part of the electron beam. Thus, the formation of the thin film can be stably performed for a long period of time while replenishing the silicon material in a melted state to the crucible.

The film formation is terminated by shielding between the crucible and the substrate by the shutter. Then, the output of the electron beam irradiating the inside of the crucible is decreased to, for example, 25 kW to suppress wasteful evaporation of the deposition material. Further, while irradiating the melt in the crucible with the electron beam, the crucible is slowly tilted, and the melt in the crucible is recovered by the melt reservoir. One specific example of the tilting is that a tilting rate is 1 degree/second and a final inclination angle is 100 degrees. However, the present embodiment is not limited to this. As the method for realizing both the tilting of the crucible and the irradiation of the melt with the electron beam, as described above, both the method for fixing the trajectory of the electron beam and controlling the trajectory of the tilting of the crucible and the method for controlling the trajectory of the electron beam based on the inclination angle are applicable.

As the melt reservoir, for example, a water-cooled copper hearth, an iron hearth, or a carbon container can be used. The water-cooled copper hearth or the iron hearth is especially desirable since these are suitable for repeated use. By using a splittable hearth in a case where the recovered melt is solidified in the shape of the rod-shaped body to be used as the supply silicon rod, the silicon rod is easily taken out of the hearth. Moreover, by configuring the melt reservoir such that the opening of the upper portion thereof is wider than the bottom portion thereof, that is, the opening is formed in a funnel shape, it is possible to prevent the melt from spilling out of the melt reservoir when recovering the melt.

In accordance with another aspect of the present invention, an elongated magnetic tape can be obtained by using band-shaped polyethylene terephthalate as the substrate, evaporating cobalt from the evaporation crucible made of magnesia, and introducing an oxygen gas to the vicinity of a film formation region.

In a case where the film formation material is a magnetic material, a magnetic force may be generated by the solidification of the film formation material in the melt reservoir after the discharge of the melt, and this may affect the trajectory of the electron beam. Therefore, it is desirable to fix or control the trajectory of the electron beam in consideration of the degree of solidification of the film formation material. Moreover, the trajectory of the electron beam may be affected in a case where the tilt mechanism or the like is constituted by the magnetic material. Therefore, it is desirable to fix or control the trajectory of the electron beam in consideration of the movement of such member constituted by the magnetic material.

The foregoing has described, as specific application examples, the battery polar plate using silicon, the electrochemical capacitor polar plate using silicon, and the magnetic tape using cobalt. However, the present invention is not limited to these. The present invention is applicable to manufacture of various devices, such as various capacitors, various sensors, solar batteries, various optical films, moisture-proof films, and electrically conductive films, the manufacture using the crucible and requiring the film formation at low cost.

### INDUSTRIAL APPLICABILITY

In accordance with the thin film manufacturing device and thin film manufacturing method of the present invention, by continuously irradiating the crucible after the film formation with the electron beam, the deposition material in the melt state can be surely taken out of the crucible. Therefore, the cracking of the crucible by the solidification of the deposition material can be prevented, and the film formation can be performed stably at low cost.

Especially, the carbon crucible easily breaks, and the influence of the cost of the crucible is large. Moreover, high stress is generated when the deposition material that is silicon solidifies. Therefore, when using the carbon crucible and the deposition material that is silicon, applying the present invention is especially significant.

### REFERENCE SIGNS LIST

1 rotational center

2 melt reservoir

3 deposition material

5 electron gun

6 main electron beam

7 shutter

8 tilt mechanism

9 evaporation crucible

10 material feed system

11 chuck roller

12 cushioning mechanism

13 feed guide

14 liquid droplet

15 thin plate

16 supply electron beam

18 deposition shield wall

19 shielding plate

21 substrate

22 vacuum chamber

23 pull-out roller

24 feed roller

25 can

27 take-up roller

29 deflection coil

30 material gas introduction tube

31 opening

32 rod-shaped body

34 exhaust pump

35 film formation width

36 main electron beam scan range

37 supply electron beam irradiation position

43 link rod

44 differential transformer

1. A thin film and rod-shaped body manufacturing device comprising:
a film forming source including a storage portion having an opening at an upper portion thereof to hold a film formation material;
an electron gun configured to irradiate the Film formation material in the storage portion with an electron beam to melt the film formation material, generate a melt, and evaporate the film formation material;
a tilt mechanism configured to tilt the film forming source from a film formation posture to an inclined posture in a direction to discharge the melt from the storage portion, the inclined posture being a posture by which the storage portion is not able to hold the melt, the direction being a direction in which an electron beam emission surface of the electron gun is located;
a melt reservoir including a horizontally laid rod-shaped recess on an upper surface thereof to receive the melt discharged from the storage portion by tilting of the film forming source;
a vacuum chamber in which the film forming source and the tilt mechanism are accommodated and a thin film is formed on a substrate; and
a vacuum pump configured to discharge air in the vacuum chamber, wherein:
a trajectory of the tilting of the film forming source or a trajectory of the electron beam is controlled such that the melt in the storage portion is continuously irradiated with the electron beam while the film forming source is tilted from the film formation posture to the inclined posture; and the melt is poured into the melt reservoir to manufacture a rod-shaped body of the film formation material.

2. (canceled)

3. The thin film and rod-shaped body manufacturing device according to claim 1, further comprising a mechanism configured to deflect the trajectory of the electron beam.

4. The thin film and rod-shaped body manufacturing device according to claim 1, further comprising a film forming source supporting mechanism configured to support the film forming source to maintain the film formation posture.

5. The thin film and rod-shaped body manufacturing device according to claim 1, wherein the film forming source is a carbon crucible.

6. The thin film and rod-shaped body manufacturing device according to claim 1, wherein the film formation material is silicon.

7. (canceled)

8. The thin film and rod-shaped body manufacturing device according to claim 1,
further comprising a material feed system configured to feed the rod-shaped body to above the film forming source, wherein
a tip end of the rod-shaped body fed by the material feed system is irradiated with the electron beam.

9. A thin film and rod-shaped body manufacturing method comprising:
a thin film forming step of irradiating a film formation material in a storage portion of a film forming source maintained in a film formation posture with an electron beam to melt the film formation material, generate a melt, evaporate the film formation material, and form the thin film on a substrate in vacuum; and
a melt discharging step of continuously irradiating the melt in the storage portion with the electron beam after the thin film forming step to maintain a state of the melt in the storage portion and tilting the film forming source from the film formation posture to an inclined posture in a direction to discharge the melt from the storage portion, the inclined posture being a posture by which the storage portion is not able to hold the melt, the direction being a direction in which an electron beam emission surface of the electron gun is located, wherein
the melt discharged in the melt discharging step is received by a melt reservoir to be recovered as a rod-shaped body of the film formation material, the melt reservoir including a horizontally laid rod-shaped recess on an upper surface thereof.

10. (canceled)

11. The thin film and rod-shaped body manufacturing method according to claim 9, wherein the electron beam has a deflected trajectory.

12. The thin film and rod-shaped body manufacturing method according to claim 9, wherein the film forming source is a carbon crucible.

13. The thin film and rod-shaped body manufacturing method according to claim 9, wherein the film formation material is silicon.

14. (canceled)

15. The thin film and rod-shaped body manufacturing method according to claim 9, further comprising:
a second film formation preparing step of putting the film forming source back to the film formation posture after the melt discharging step, supplying the film formation material to the storage portion of the film forming source, and providing the rod-shaped body at a material feed system;
a second thin film forming step of irradiating the film formation material in the storage portion of the film forming source maintained in the film formation posture with the electron beam after the second film formation preparing step to melt the film formation material, evaporate the film formation material, and form the thin film again on the substrate in vacuum; and
a material supplying step of, while moving a tip end of the rod-shaped body to above the film forming source by the material feed system, irradiating the tip end with the electron beam in the second thin film forming step to melt the tip end and supply the obtained melted material to the film forming source.

16. (canceled)
